(19) United States
(12) Patent Application Publication
(10) Pub. No.: US 2026/0301673 A1
(43) Pub. Date: Oct. 1, 2026

(54) DISPLAY DEVICE AND ELECTRONIC DEVICE INCLUDING THE DISPLAY DEVICE

(71) Applicant: SAMSUNG DISPLAY CO., LTD., YONGIN-SI (KR)

(72) Inventor: SI-BEAK PYO, Yongin-si (KR)

(21) Appl. No.: 19/451,207

(22) Filed: Jan. 16, 2026

(30) Foreign Application Priority Data
Mar. 28, 2025 (KR) 10-2025-0040373

(51) Int. Cl. G09G 3/3233

(52) U.S. Cl. CPC G09G 3/3233; G09G 2300/0814; G09G 2310/08; G09G 2320/041; G09G 2330/021; G09G 2330/028

(57) ABSTRACT

A reference voltage, a data drive voltage and a difference value between an anode initialization voltage and a second power supply voltage are controlled according to an average image level of input image data.

### CROSS-REFERENCE TO RELATED APPLICATIONS

This application claims priority under 35 USC § 119 to and benefits from Korean Patent Application No. 10-2025-0040373 filed on Mar. 28, 2025 in the Korean Intellectual Property Office (KIPO), the entire contents of which is incorporated by reference herein.

### TECHNICAL FIELD

Embodiments of the disclosure relate to a display device and an electronic device including the display device for reducing a power consumption.

### DISCUSSION OF THE RELATED ART

In general, a display device includes a display panel and a display panel driver. The display panel includes gate lines, data lines, emission lines, and pixels. The display panel driver includes a gate driver for providing a gate signal to the gate lines, a data driver for providing a data voltage to the data lines, an emission driver for providing an emission signal to the emission lines, and a driving controller that controls the gate driver, the data driver, and the emission driver.

To reduce a power consumption of the display device, voltages applied to the pixels may be reduced. However, in a case where voltages applied to the pixels are reduced, problems may occur in which FFR (First Frame Response) characteristics and TLS (Temperature Luminance Sensitivity) characteristics deteriorate.

### SUMMARY

Embodiments of the disclosure supply a display device for reducing a power consumption and maintaining a display quality.

Embodiments of the disclosure supply an electronic device including the display device.

In an embodiment of a display device according to the disclosure, the display device includes a display panel including a pixel driven based on a first power supply voltage and a second power supply voltage, and a display panel driver. The display panel driver is configured to generate a data driving voltage, configured to generate a gamma reference voltage by dividing the data driving voltage, to configured generate a data voltage based on input image data by dividing the data driving voltage and the gamma reference voltage, and configured to supply the data voltage to the pixel. The pixel includes a driving transistor configured to generate a driving current, a data write transistor configured to supply the data voltage to the driving transistor, a reset transistor configured to supply a reference voltage to a gate electrode of the driving transistor, a light emitting diode configured to emit light based on the driving current, and an anode initialization transistor configured to supply an anode initialization voltage to an anode electrode of the light emitting diode. The display panel driver is further configured to control the reference voltage, the data driving voltage, and a difference value between the anode initialization voltage and the second power supply voltage based on an average picture level (APL) of the input image data.

In an embodiment, the display panel driver may be further configured to reduce the difference value between the anode initialization voltage and the second power supply voltage when the average picture level of the input image data increases.

In an embodiment, the display panel driver may be further configured to reduce the reference voltage when the average picture level of the input image data increases.

In an embodiment, the display panel driver may be further configured to perform a gamma compensation to compensate for the data voltage based on the reference voltage.

In an embodiment, the display panel driver may be further configured to increase the data driving voltage when the average picture level of the input image data increases.

In an embodiment, the data driving voltage may be a sum of the reference voltage, a maximum grayscale voltage of the data voltage, and a headroom when the average picture level of the input image data is greater than an APL threshold. The data driving voltage may be a sum of the reference voltage and the headroom when the average picture level of the input image data is less than or substantially equal to the APL threshold.

In an embodiment, the display panel driver may be further configured to calculate the average picture level of the input image data over a plurality of frames.

In an embodiment, the driving transistor may include a gate electrode connected to a first node, a first electrode, and a second electrode connected to a second node. The data write transistor may include a gate electrode configured to receive a data write gate signal, a first electrode configured to receive the data voltage, and a second electrode connected to the first node. The reset transistor may include a gate electrode configured to receive a reset gate signal, a first electrode configured to receive the reference voltage, and a second electrode connected to the first node. The anode initialization transistor may include a gate electrode configured to receive an initialization gate signal, a first electrode configured to receive the anode initialization voltage, and a second electrode connected to a third node. The light emitting diode may include the anode electrode connected to the third node and a cathode electrode configured to receive the second power supply voltage.

In an embodiment, the pixel may further include a first light emitting control transistor and a second light emitting control transistor configured to control light emission of the light emitting diode. The first light emitting control transistor may include a gate electrode configured to receive a first emission signal, a first electrode configured to receive the first power supply voltage, and a second electrode connected to the first electrode of the driving transistor. The second light emitting control transistor may include a gate electrode configured to receive a second emission signal, a first electrode connected to the second node, and a second electrode connected to the third node.

In an embodiment, the pixel may further include a storage capacitor including a first electrode connected to the first node and a second electrode connected to the second node.

In an embodiment, the driving transistor may further include a back gate electrode connected to the second node. The pixel may further include a hold capacitor including a first electrode configured to receive the first power supply voltage and a second electrode connected to the second node.

In an embodiment of an electronic device according to the disclosure, the electronic device includes a display panel including a pixel driven based on a first power supply voltage and a second power supply voltage, a display panel driver. The display panel driver is configured to generate a data driving voltage, configured to generate a gamma reference voltage by dividing the data driving voltage, configured to generate a data voltage based on input image data by dividing the data driving voltage and the gamma reference voltage, and configured to supply the data voltage to the pixel, and a processor configured to control the display panel driver. The pixel includes a driving transistor configured to generate a driving current, a data write transistor configured to supply the data voltage to the driving transistor, a reset transistor configured to supply a reference voltage to a gate electrode of the driving transistor, a light emitting diode configured to emit light based on the driving current, and an anode initialization transistor configured to supply an anode initialization voltage to an anode electrode of the light emitting diode. The display panel driver is further configured to control the reference voltage, the data driving voltage, and a difference value between the anode initialization voltage and the second power supply voltage based on an average picture level (APL) of the input image data.

In an embodiment, the display panel driver may be further configured to reduce the difference value between the anode initialization voltage and the second power supply voltage when the average picture level of the input image data increases.

In an embodiment, the display panel driver may be further configured to reduce the reference voltage when the average picture level of the input image data increases.

In an embodiment, the display panel driver may be further configured to perform a gamma compensation to compensate for the data voltage based on the reference voltage.

In an embodiment, the display panel driver may be further configured to increase the data driving voltage when the average picture level of the input image data increases.

In an embodiment, the data driving voltage may be a sum of the reference voltage, a maximum grayscale voltage of the data voltage, and a headroom when the average picture level of the input image data is greater than an APL threshold. The data driving voltage may be a sum of the reference voltage and the headroom when the average picture level of the input image data is less than or substantially equal to the APL threshold.

In an embodiment, the display panel driver may be further configured to calculate the average picture level of the input image data over a plurality of frames.

In an embodiment, the driving transistor may include a gate electrode connected to a first node, a first electrode, and a second electrode connected to a second node. The data write transistor may include a gate electrode configured to receive a data write gate signal, a first electrode configured to receive the data voltage, and a second electrode connected to the first node. The reset transistor may include a gate electrode configured to receive a reset gate signal, a first electrode configured to receive the reference voltage, and a second electrode connected to the first node. The anode initialization transistor may include a gate electrode configured to receive an initialization gate signal, a first electrode configured to receive the anode initialization voltage, and a second electrode connected to a third node. The light emitting diode may include the anode electrode connected to the third node and a cathode electrode configured to receive the second power supply voltage.

In an embodiment, the pixel may further include a first light emitting control transistor and a second light emitting control transistor configured to control light emission of the light emitting diode. The first light emitting control transistor may include a gate electrode configured to receive a first emission signal, a first electrode configured to receive the first power supply voltage, and a second electrode connected to the first electrode of the driving transistor. The second light emitting control transistor may include a gate electrode configured to receive a second emission signal, a first electrode connected to the second node, and a second electrode connected to the third node.

In a display device and the electronic device according to embodiments of the disclosure, the reference voltage, the data driving voltage, and the difference value between the anode initialization voltage and the second power supply voltage may be controlled according to the average image level of the input image data. Accordingly, the power consumption may be reduced while maintaining a display quality (e.g., FFR characteristics and TLS characteristics).

### BRIEF DESCRIPTION OF THE DRAWINGS

The above and other features of embodiments of the disclosure will become more apparent by describing in detailed embodiments thereof with reference to the accompanying drawings, in which:

FIG. 1 is a block diagram showing a display device according to embodiments of the disclosure;

FIG. 2 is a circuit diagram showing an example of a pixel of FIG. 1;

FIG. 3 is a timing diagram showing an example of an operation of a pixel of FIG. 2;

FIG. 4 is a circuit diagram showing an example of an operation of a pixel of FIG. 2 in an initialization period of FIG. 3;

FIG. 5 is a circuit diagram showing an example of an operation of a pixel of FIG. 2 in a compensation period of FIG. 3;

FIG. 6 is a circuit diagram showing an example of an operation of a pixel of FIG. 2 in a data write period of FIG. 3;

FIG. 7 is a circuit diagram showing an example of an operation of a pixel of FIG. 2 in a light emission period of FIG. 3;

FIG. 8 is a circuit diagram showing a power consumption and a display quality of a pixel of FIG. 2 according to a data driving voltage, a data voltage, a reference voltage, an anode initialization voltage, and a second power supply voltage;

FIG. 9 is a flowchart showing a method of setting voltages according to an average picture level of input image data according to an embodiment of the disclosure;

FIG. 10 is a table showing voltages set according to a voltage setting method in the flowchart of FIG. 9 according to an embodiment of the disclosure;

FIG. 11 is a flowchart showing a method of controlling voltages according to an average picture level of an input image data according to an embodiment of the disclosure;

FIG. 12 is a block diagram showing an electronic device according to an embodiment of the disclosure;

FIG. 13 is a diagram showing an example in which the electronic device of FIG. 12 is implemented as a smart phone;

FIG. 14 is a block diagram showing an electronic device according to an embodiment of the disclosure; and

FIG. 15 are schematic diagrams showing electronic devices of FIG. 14.

### DETAILED DESCRIPTION OF EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When an embodiment may be implemented differently, a specific process order may be performed differently from the described order. For example, two consecutively described processes may be performed substantially at the same time or performed in an order opposite to the described order. Also, like reference numerals and/or reference characters denote like elements.

The term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

According to embodiments of the disclosure, a display device and an electronic device that includes the same allows for less power consumption without reducing image quality. The display (or image) quality are determined based on first frame response (FFR) characteristics and temperature luminance sensitivity (TLS) characteristics. These goals are achieved by controlling each of a reference voltage, a data driving voltage, and a difference value between an anode initialization voltage and a second power supply voltage based on an average picture level (APL) of the image input data.

In order to achieve these goals, a driving controller of a display panel driver receives input image data and determines an average picture level from multiple successive frames of input image data. The average picture data may then be used to determine the reference voltage, the data driving voltage, and the difference value between the anode initialization voltage and the second power supply voltage. Then, the driving controller is configured to perform gamma compensation in which the data voltage is compensated based on the reference voltage. Then, the display device is configured to display the image based on the reference voltage, the data driving voltage, the compensated data voltage, and the difference value between the anode initialization voltage and the second power supply voltage. Accordingly, the display quality can be maintained while power consumption may be reduced.

Hereinafter, the disclosure will be described in more detail with reference to the accompanying drawings.

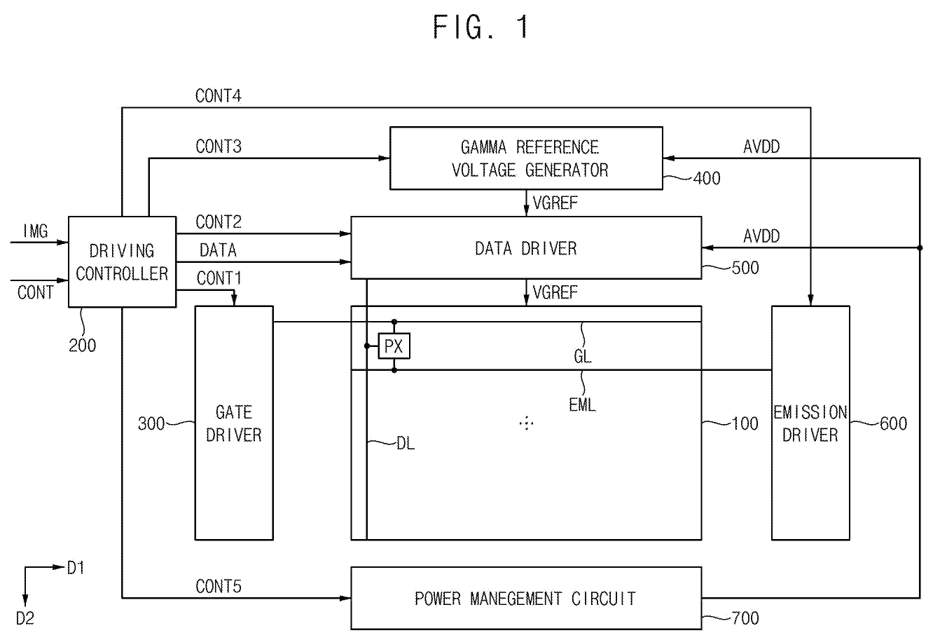

FIG. 1 is a block diagram showing a display device according to embodiments of the disclosure.

Referring to FIG. 1, a display device may include a display panel 100 and a display panel driver. The display panel driver may include a driving controller 200, a gate driver 300, a gamma reference voltage generator 400, and a data driver 500. The display panel driver may further include an emission driver 600. The display device may further include a power management circuit 700.

For example, the driving controller 200 and the data driver 500 may be a single, uninterrupted structure. For example, the driving controller 200, the gamma reference voltage generator 400, and the data driver 500 may be a single, uninterrupted structure (i.e., may be formed integrally). For example, the driving controller 200, the gate driver 300, the gamma reference voltage generator 400, and the data driver 500 may be a single, uninterrupted structure. For example, the driving controller 200, the gate driver 300, the gamma reference voltage generator 400, the data driver 500, and the emission driver 600 may be a single, uninterrupted structure. For example, the driving controller 200, the gate driver 300, the gamma reference voltage generator 400, the data driver 500, the emission driver 600, and the power management circuit 700 may be a single, uninterrupted structure. A driving module in which at least the driving controller 200 and the data driver 500 are a single, uninterrupted structure may be named a timing controller embedded data driver (TED).

The display panel 100 may include a display area for displaying an image and a peripheral area disposed adjacent to the display area.

For example, the display panel 100 may be an organic light-emitting diode display panel including an organic light emitting diode. For example, the display panel 100 may be a quantum-dot organic light emitting diode display panel including an organic light emitting diode and a quantum-dot color filter. For example, the display panel 100 may be a quantum-dot nano light emitting diode display panel including a nano light emitting diode and a quantum-dot color filter.

The display panel 100 may include gate lines GL, data lines DL, emission lines EML, and pixels PX electrically connected to the gate lines GL, the data lines DL, and the emission lines EML, respectively. The gate lines GL may extend in a first direction D1, the data lines DL may extend in a second direction D2 intersecting the first direction D1, and the emission lines EML may extend in the first direction D1.

The driving controller 200 may receive input image data IMG and an input control signal CONT from an external device. For example, the input image data IMG may typically include red image data, green image data and blue image data. The input image data IMG may typically include white image data. The input image data IMG may typically include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, a third control signal CONT3, a fourth control signal CONT4, a fifth control signal CONT5, and a data signal DATA based on the input image data IMG and the input control signal CONT.

The driving controller 200 may generate the first control signal CONT1 that controls an operation of the gate driver 300 based on the input control signal CONT, and that outputs the first control signal CONT1 to the gate driver 300. The first control signal CONT1 may include a vertical start signal and a gate clock signal.

The driving controller 200 may generate the second control signal CONT2 that controls an operation of the data driver 500 based on the input control signal CONT, and that outputs the second control signal CONT2 to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 that controls an operation of the gamma reference voltage generator 400 based on the input control signal CONT, and that outputs the third control signal CONT3 to the gamma reference voltage generator 400.

The driving controller 200 may generate the fourth control signal CONT4 that controls an operation of the emission driver 600 based on the input control signal CONT, and that outputs the fourth control signal CONT4 to the emission driver 600.

The driving controller 200 may generate the fifth control signal CONT5 that controls an operation of the power management circuit 700 based on the input control signal CONT, and that outputs the fifth control signal CONT5 to the emission driver 600.

The gate driver 300 may generate gate signals for driving the gate lines GL in response to the first control signal CONT1 received from the driving controller 200. The gate driver 300 may output the gate signals to the gate lines GL.

In an embodiment, the gate driver 300 and the peripheral area of the display panel 100 may be a single, uninterrupted structure. In an embodiment, the gate driver 300 may be mounted into the peripheral area of the display panel 100.

The gamma reference voltage generator 400 may receive the third control signal CONT3 from the driving controller 200 and may receive a data driving voltage AVDD from the power management circuit 700. The gamma reference voltage generator 400 may divide the data driving voltage AVDD to generate a gamma reference voltage VGREF. The gamma reference voltage generator 400 may supply the gamma reference voltage VGREF to the data driver 500. The gamma reference voltage VGREF may have a value corresponding to each data signal DATA.

For example, the gamma reference voltage generator 400 may be disposed in the driving controller 200 or may be disposed in the data driver 500.

The data driver 500 may receive the second control signal CONT2 and the data signal DATA from the driving controller 200, the gamma reference voltage VGREF from the gamma reference voltage generator 400, and the data driving voltage AVDD from the power management circuit 700. The data driver 500 may divide the data driving voltage AVDD and the gamma reference voltage VGREF to convert the data signal DATA into an analog data voltage. The data driver 500 may output the data voltage to the data line DL.

In an embodiment, the data driver 500 and the peripheral area of the display panel 100 may be a single, uninterrupted structure. In an embodiment, the data driver 500 may be mounted in the peripheral area of the display panel 100.

The emission driver 600 may generate emission signals for driving the emission lines EML in response to the fourth control signal CONT4 received from the driving controller 200. The emission driver 600 may output the emission signals to the emission lines EML.

In an embodiment, the emission driver 600 and the peripheral area of the display panel 100 may be a single, uninterrupted structure. In an embodiment, the emission driver 600 may be mounted in the peripheral area of the display panel 100.

In FIG. 1, for a convenience of an explanation, the gate driver 300 may be disposed on a first side of the display panel 100 and the emission driver 600 may be disposed on a second side of the display panel 100. Although shown, the disclosure is not necessarily limited thereto. For example, both the gate driver 300 and the emission driver 600 may be disposed on the first side of the display panel 100. For example, both the gate driver 300 and the emission driver 600 may be disposed on both sides of the display panel 100. For example, the gate driver 300 and the emission driver 600 may be a single, uninterrupted structure (i.e., be formed integrally).

The power management circuit 700 may generate the data driving voltage AVDD in response to the fifth control signal CONT5 received from the driving controller 200. The power management circuit 700 may supply the data driving voltage AVDD to the gamma reference voltage generator 400 and the data driver 500.

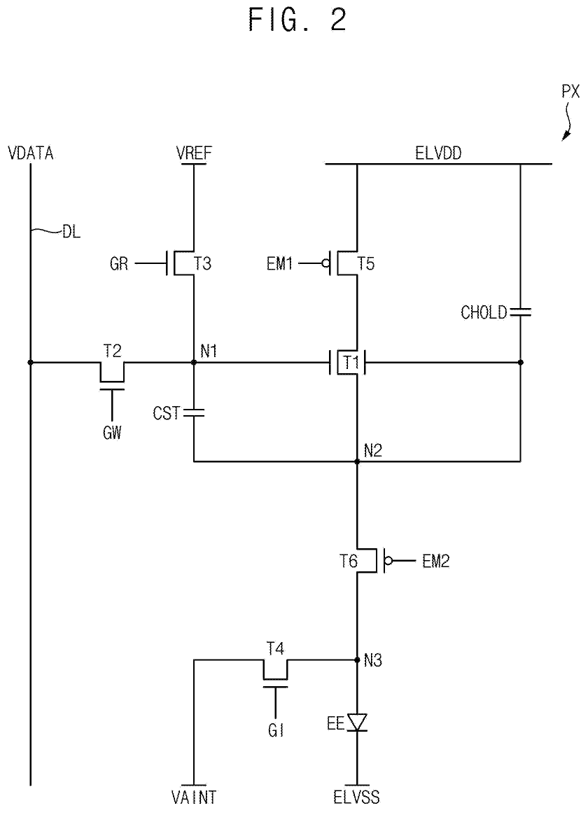

FIG. 2 is a circuit diagram showing an example of a pixel PX of FIG. 1.

Referring to FIGS. 1 and 2, the display panel 100 may include the pixel PX. The pixel PX may include a first transistor T1, a second transistor T2, a third transistor T3, a fourth transistor T4, a fifth transistor T5, a sixth transistor T6, a storage capacitor CST, a hold capacitor CHOLD, and a light emitting diode EE.

In an embodiment, the fifth transistor T5 and the sixth transistor T6 may be PMOS transistors, and the first transistor T1, the second transistor T2, the third transistor T3, and the fourth transistor T4 may be NMOS transistors.

The PMOS transistor may be turned on when a gate-source voltage of the PMOS transistor is less than or substantially equal to a threshold voltage (e.g., a negative value) of the PMOS transistor. On the other hand, the PMOS transistor may be turned off when the gate-source voltage of the PMOS transistor is greater than the threshold voltage of the PMOS transistor. For example, when a gate signal having a low level is applied to a gate electrode of the PMOS transistor, the PMOS transistor may be turned on. For example, when a gate signal having a high level is applied to the gate electrode of the PMOS transistor, the PMOS transistor may be turned off. Therefore, a turn-on level of the PMOS transistor may be the low level.

The NMOS transistor may be turned on when a gate-source voltage of the NMOS transistor is greater than or substantially equal to a threshold voltage (e.g., a positive value) of the NMOS transistor. On the other hand, the NMOS transistor may be turned off when the gate-source voltage of the NMOS transistor is less than the threshold voltage of the NMOS transistor. For example, when a gate signal having the high level is applied to a gate electrode of the NMOS transistor, the NMOS transistor may be turned on. For example, when a gate signal having the low level is applied to the gate electrode of the NMOS transistor, the NMOS transistor may be turned off. Therefore, the turn-on level of the NMOS transistor may be the high level.

The first transistor T1 may include a gate electrode connected to a first node N1, a first electrode, a second electrode connected to a second node N2, and a back gate electrode connected to the second node N2. The first transistor T1 may be turned on based on a voltage of the first node N1 and a voltage of the second node N2 to generate a driving current. For example, the first transistor T1 may generate the driving current based on a difference value between the voltage of the first node N1 and the voltage of the second node N2. Therefore, as the difference value between the voltage of the first node N1 and the voltage of the second node N2 increases, a magnitude of the driving current may increase. For example, the first transistor T1 may be referred to as a driving transistor.

The second transistor T2 may include a gate electrode that receives a data write gate signal GW, a first electrode connected to a data line DL transmitting a data voltage VDATA, and a second electrode connected to the first node N1. The second transistor T2 may be turned on in response to a data write gate signal GW having the high level to supply the data voltage VDATA to the first node N1. For example, the second transistor T2 may be referred to as a data write transistor.

The third transistor T3 may include a gate electrode that receives a reset gate signal GR, a first electrode that receives a reference voltage VREF, and a second electrode connected to the first node N1. The third transistor T3 may be turned on in response to a reset gate signal GR having the high level to supply the reference voltage VREF to the first node N1. For example, the third transistor T3 may be referred to as a reset transistor.

The fourth transistor T4 may include a gate electrode that receives an initialization gate signal GI, a first electrode that receives an anode initialization voltage VAINT, and a second electrode connected to a third node N3. The fourth transistor T4 may be turned on in response to an initialization gate signal GI having the high level to supply the anode initialization voltage VAINT to the third node N3. For example, the fourth transistor T4 may be referred to as an anode initialization transistor.

The fifth transistor T5 may include a gate electrode that receives a first emission signal EM1, a first electrode that receives a first power supply voltage ELVDD, and a second electrode connected to the first electrode of the first transistor T1. The sixth transistor T6 may include a gate electrode that receives a second emission signal EM2, a first electrode connected to the second node N2, and a second electrode connected to a third node N3. The fifth transistor T5 may control an application of the driving current to the light emitting diode EE in response to the first emission signal EM1 to control a light emission of the light emitting diode EE. The sixth transistor T6 may control the driving current applied to the light emitting diode EE in response to the second emission signal EM2 to control the light emission of the light emitting diode EE. For example, the fifth transistor T5 may be referred to as a first light emitting control transistor, and the sixth transistor T6 may be referred to as a second light emitting control transistor.

The storage capacitor CST may include a first electrode connected to the first node N1 and a second electrode connected to the second node N2. The storage capacitor CST may store the data voltage VDATA.

The hold capacitor CHOLD may include a first electrode that receives the first power supply voltage ELVDD and a second electrode connected to the second node N2. The hold capacitor CHOLD may hold the voltage of the second node N2.

The light emitting diode EE may include an anode electrode connected to the third node N3 and a cathode electrode that receives a second power supply voltage ELVSS. The light emitting diode EE may emit light based on the driving current. As the magnitude of the driving current increases, a luminance corresponding to a light emission intensity of the light emitting diode EE may increase.

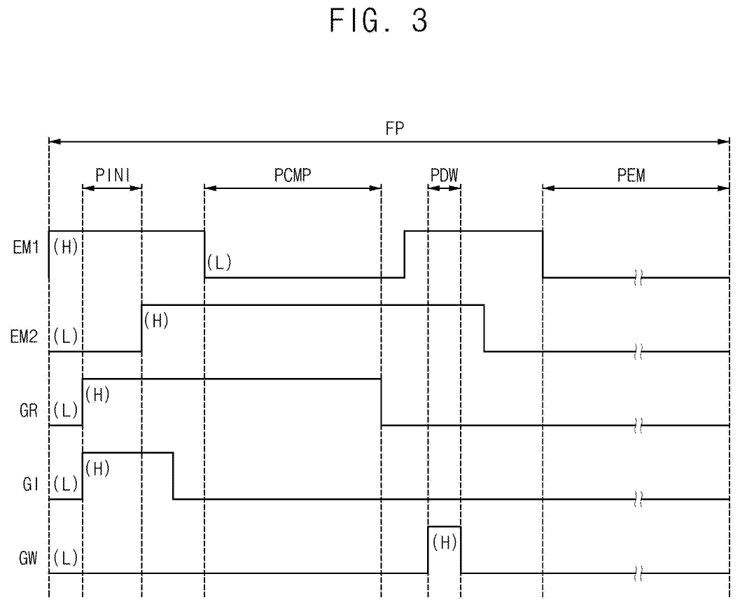

FIG. 3 is a timing diagram showing an example of an operation of a pixel PX of FIG. 2.

Referring to FIGS. 1 to 3, the pixel PX may operate in frame units or frame periods FP. A frame period FP of the pixel PX may include an initialization period PINI, a compensation period PCMP, a data write period PDW, and a light emission period PEM.

In the initialization period PINI, the first emission signal EM1 may have the high level H, the second emission signal EM2 may have the low level L, the reset gate signal GR may have the high level H, the initialization gate signal GI may have the high level H, and the data write gate signal GW may have the low level L. Here, the low level L represents a lower voltage than the high level H.

In the compensation period PCMP, the first emission signal EM1 may have the low level L, the second emission signal EM2 may have the high level H, the reset gate signal GR may have the high level H, the initialization gate signal GI may have the low level L, and the data write gate signal GW may have the low level L.

In the data write period PDW, the first emission signal EM1 may have the high level H, the second emission signal EM2 may have the high level H, the reset gate signal GR may have the low level L, the initialization gate signal GI may have the low level L, and the data write gate signal GW may have the high level H.

In the light emission period PEM, the first emission signal EM1 may have the low level L, the second emission signal EM2 may have the low level L, the reset gate signal GR may have the low level L, the initialization gate signal GI may have the low level L, and the data write gate signal GW may have the low level L.

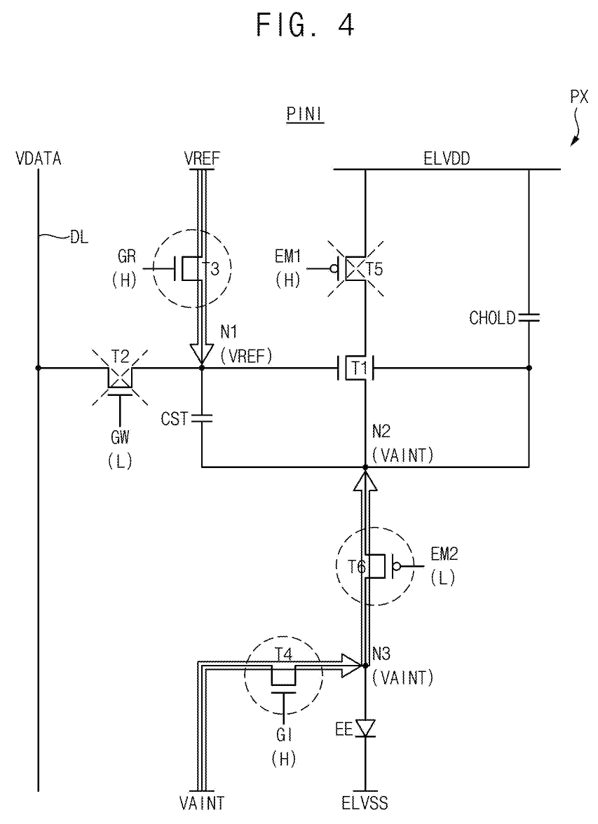

FIG. 4 is a circuit diagram showing an example of an operation of a pixel PX of FIG. 2 in an initialization period PINI of FIG. 3.

Referring to FIGS. 1 to 4, in the initialization period PINI, the second transistor T2 may be turned off in response to the data write gate signal GW having the low level L, the third transistor T3 may be turned on in response to the reset gate signal GR having the high level H, the fourth transistor T4 may be turned on in response to the initialization gate signal GI having the high level H, the fifth transistor T5 may be turned off in response to the first emission signal EM1 having the high level H, and the sixth transistor T6 may be turned on in response to the second emission signal EM2 having the low level L.

The fourth transistor T4 may be turned on to supply the anode initialization voltage VAINT to the third node N3. Therefore, a voltage of the third node N3 may have a potential equal to the anode initialization voltage VAINT. Since the anode electrode of the light emitting diode EE is connected to the third node N3, a voltage of the anode electrode of the light emitting diode EE may be initialized to the anode initialization voltage VAINT.

The sixth transistor T6 may be turned on to supply the voltage of the third node N3 to the second node N2. Therefore, the voltage of the second node N2 may have a potential equal to the anode initialization voltage VAINT. Since the second electrode of the first transistor T1 is connected to the second node N2, the voltage of the second electrode of the first transistor T1 may be initialized to the anode initialization voltage VAINT.

The third transistor T3 may be turned on to supply the reference voltage VREF to the first node N1. Therefore, the voltage of the first node N1 may have a potential equal to the reference voltage VREF. Since the gate electrode of the first transistor T1 is connected to the first node N1, a voltage of the gate electrode of the first transistor T1 may be initialized to the reference voltage VREF.

Since the first electrode of the storage capacitor CST is connected to the first node N1, a voltage of the first electrode of the storage capacitor CST may be initialized to the reference voltage VREF. Since the second electrode of the storage capacitor CST is connected to the second node N2, a voltage of the second electrode of the storage capacitor CST may be initialized to the anode initialization voltage VAINT.

As such, in the initialization period PINI, initialization operations may be performed on the voltage of the gate electrode of the first transistor T1, the voltage of the second electrode of the first transistor T1, the voltage of the first electrode of the storage capacitor CST, the voltage of the second electrode of the storage capacitor CST, and the voltage of the anode electrode of the light emitting diode EE.

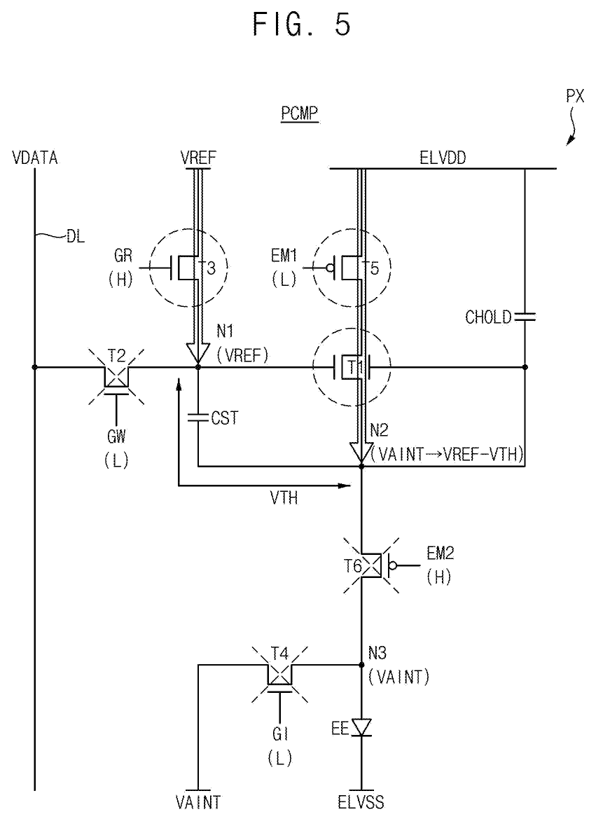

FIG. 5 is a circuit diagram showing an example of an operation of a pixel PX of FIG. 2 in a compensation period PCMP of FIG. 3.

Referring to FIGS. 1 to 5, in the compensation period PCMP, the second transistor T2 may be turned off in response to the data write gate signal GW having the low level L, the third transistor T3 may be turned on in response to the reset gate signal GR having the high level H, the fourth transistor T4 may be turned off in response to the initialization gate signal GI having the low level L, the fifth transistor T5 may be turned on in response to the first emission signal EM1 having the low level L, and the sixth transistor T6 may be turned off in response to the second emission signal EM2 having the high level H.

The third transistor T3 may be turned on to supply the reference voltage VREF to the first node N1. Therefore, the voltage of the first node N1 may have a potential equal to the reference voltage VREF. Since the gate electrode of the first transistor T1 is connected to the first node N1, the voltage of the gate electrode of the first transistor T1 may be initialized to the reference voltage VREF.

The fifth transistor T5 may be turned on to supply the first power supply voltage ELVDD to the first electrode of the first transistor T1. Therefore, a voltage of the first electrode of the first transistor T1 may have a potential (or voltage) equal to the first power supply voltage ELVDD.

The voltage of the gate electrode of the first transistor T1 may be the reference voltage VREF, and the voltage of the second electrode (i.e., a source electrode) of the first transistor T1 may be the anode initialization voltage VAINT. In this case, the gate-source voltage (i.e., VREF – VAINT) of the first transistor T1 may be greater than or substantially equal to a threshold voltage VTH of the first transistor T1. Therefore, the first transistor T1 may be turned on. The first transistor T1 may be turned on until the voltage of the second node N2 has a potential equal to a voltage (i.e., VREF – VTH) obtained by subtracting the threshold voltage VTH of the first transistor T1 from the reference voltage VREF.

Since the voltage of the first node N1 is the reference voltage VREF and the voltage of the second node N2 is the voltage obtained by subtracting the threshold voltage VTH of the first transistor T1 from the reference voltage VREF (i.e., VREF – VTH), the storage capacitor CST may store the threshold voltage VTH of the first transistor T1 between the first electrode of the storage capacitor CST and the second electrode of the storage capacitor CST.

As such, in the compensation period PCMP, since the storage capacitor CST stores the threshold voltage VTH of the first transistor T1, a compensation operation for the threshold voltage VTH of the first transistor T1 may be performed.

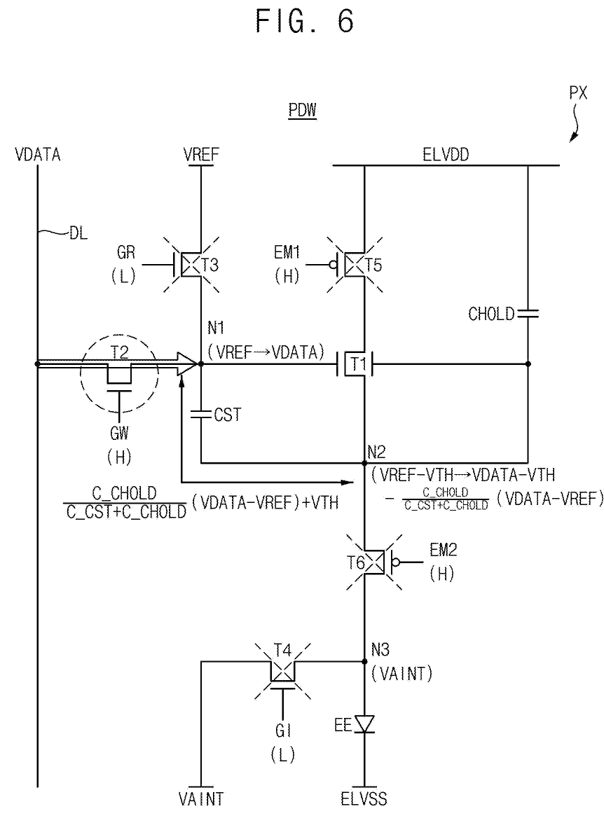

FIG. 6 is a circuit diagram showing an example of an operation of a pixel PX of FIG. 2 in a data write period PDW of FIG. 3.

Referring to FIGS. 1 to 6, in the data write period PDW, the second transistor T2 may be turned on in response to the data write gate signal GW having the high level H, the third transistor T3 may be turned off in response to the reset gate signal GR having the low level L, the fourth transistor T4 may be turned off in response to the initialization gate signal GI having the low level L, the fifth transistor T5 may be turned off in response to the first emission signal EM1 having the high level H, and the sixth transistor T6 may be turned off in response to the second emission signal EM2 having the high level H.

The second transistor T2 may be turned on to supply the data voltage VDATA transmitted through the data line DL to the first node N1. Therefore, the voltage (or potential) of the first node N1 may change from the reference voltage VREF to the data voltage VDATA by a difference value (i.e., VDATA – VREF) between the data voltage VDATA and the reference voltage VREF.

Since the storage capacitor CST and the hold capacitor CHOLD are connected in series, when the voltage of the first node N1 changes by the difference value (i.e., VDATA – VREF) between the data voltage VDATA and the reference voltage VREF, the voltage of the second node N2 may change by C_CHOLD/(C_CST+C_CHOLD) × (VDATA–VREF). (Here, C_CHOLD is a capacitance of the hold capacitor CHOLD, and C_CST is a capacitance of the storage capacitor CST.) Therefore, the voltage of the second node N2 may be changed to VDATA - VTH - C_CHOLD/(C_CST+C_CHOLD) × (VDATA–VREF).

Since the voltage of the first node N1 is the data voltage VDATA and the voltage of the second node N2 is VDATA - VTH - C_CHOLD/(C_CST+C_CHOLD) × (VDATA–VREF), the storage capacitor CST may store C_CHOLD/(C_CST+C_CHOLD) × (VDATA–VREF) + VTH between the first electrode of the storage capacitor CST and the second electrode of the storage capacitor CST. For example, the storage capacitor CST may store a component of the data voltage VDATA.

As such, in the data write period PDW, a data write operation for the pixel PX may be performed.

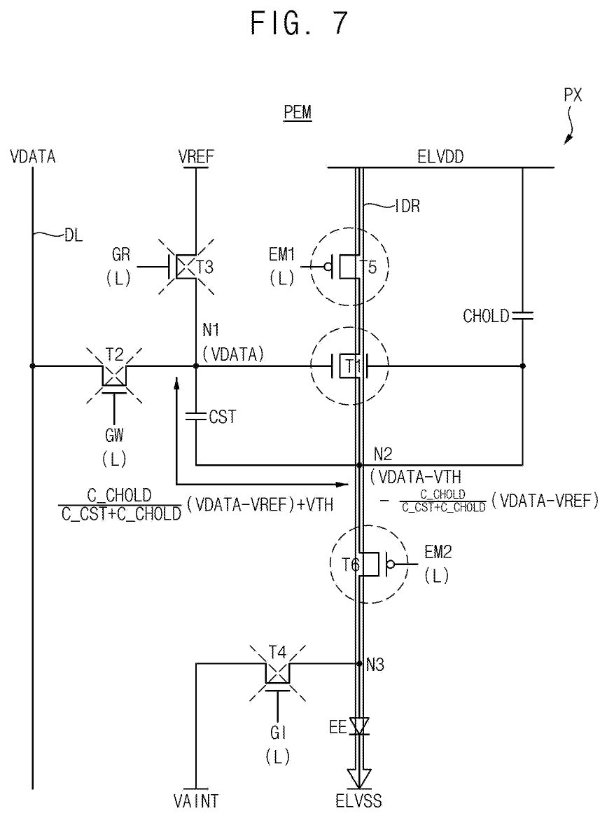

FIG. 7 is a circuit diagram showing an example of an operation of a pixel PX of FIG. 2 in a light emission period PEM of FIG. 3.

Referring to FIGS. 1 to 7, in the light emission period PEM, the second transistor T2 may be turned off in response to the data write gate signal GW having the low level L, the third transistor T3 may be turned off in response to the reset gate signal GR having the low level L, the fourth transistor T4 may be turned off in response to the initialization gate signal GI having the low level L, the fifth transistor T5 may be turned on in response to the first emission signal EM1 having the low level L, and the sixth transistor T6 may be turned on in response to the second emission signal EM2 having the low level L.

The first transistor T1 may be turned on based on the voltage of the first node N1 and the voltage of the second node N2 to generate the driving current IDR. For example, the first transistor T1 may generate the driving current IDR based on the gate-source voltage (i.e., C_CHOLD/(C_CST+C_CHOLD) × (VDATA–VREF) + VTH) of the first transistor T1. Since the gate-source voltage (i.e., C_CHOLD/(C_CST+C_CHOLD) × (VDATA–VREF) + VTH) of the first transistor T1 includes the component of the data voltage VDATA, the magnitude of the driving current IDR may vary according to the data voltage VDATA.

Since not only the first transistor T1 but also the fifth transistor T5 and the sixth transistor T6 are turned on, a transmission line of the driving current IDR may be formed between a line transmitting the first power supply voltage ELVDD and a line transmitting the second power supply voltage ELVSS.

Accordingly, the driving current IDR may be transmitted to the light emitting diode EE along the transmission line of the driving current IDR. The light emitting diode EE may emit the light based on the driving current IDR. As the magnitude of the driving current IDR increases, the luminance corresponding to the light emission intensity of the light emitting diode EE may increase.

As such, in the light emission period PEM, a light emission operation may be performed for the light emitting diode EE.

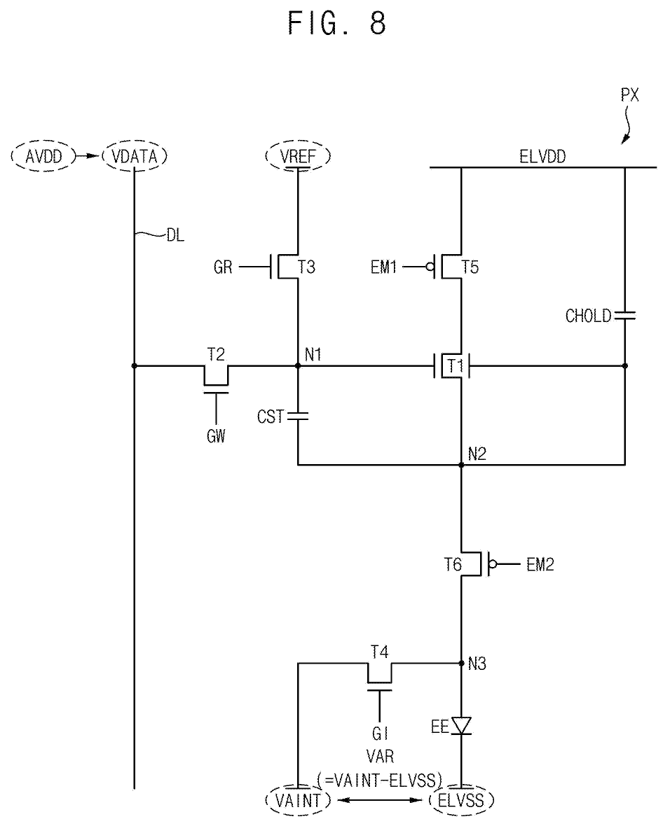

FIG. 8 is a circuit diagram showing a power consumption and a display quality of a pixel PX of FIG. 2 according to a data driving voltage AVDD, a data voltage VDATA, a reference voltage VREF, an anode initialization voltage VAINT, and a second power supply voltage ELVSS.

Referring to FIGS. 1 to 8, a display device according to embodiments of the disclosure may reduce a power consumption while controlling the data driving voltage AVDD, the reference voltage VREF, the anode initialization voltage VAINT, and the second power supply voltage ELVSS to maintain a display quality.

The display quality (e.g., First Frame Response (FFR)) characteristics and Temperature Luminance Sensitivity (TLS) characteristics may vary according to a difference value VAR between the anode initialization voltage VAINT and the second power supply voltage ELVSS. Here, the FFR characteristics indicates a speed of a luminance change according to a change in an input grayscale (i.e., a grayscale of input image data IMG), and the TLS characteristics indicates the speed of luminance change according to a change in temperature.

For example, when the difference value VAR between the anode initialization voltage VAINT and the second power supply voltage ELVSS is large, the display quality (e.g., the FFR characteristics and the TLS characteristics) may be good. For example, when the difference value VAR between the anode initialization voltage VAINT and the second power supply voltage ELVSS is small, the display quality (e.g., the FFR characteristics and the TLS characteristics) may be poor.

However, when the difference value VAR between the anode initialization voltage VAINT and the second power supply voltage ELVSS is large, the display quality (e.g., the FFR characteristics and the TLS characteristics) may improve, but the power consumption may increase. For example, when the difference value VAR between the anode initialization voltage VAINT and the second power supply voltage ELVSS is large, the display quality (e.g., the FFR characteristics and the TLS characteristics) may improve, but a black corresponding to a grayscale of zero might not be completely implemented. To solve this problem, when the input grayscale is 0, the driving current IDR should be small. The magnitude of the driving current IDR is determined based on the gate-source voltage of the first transistor T1, and the gate-source voltage of the first transistor T1 is C_CHOLD/(C_CST+C_CHOLD) × (VDATA–VREF) + VTH. Therefore, in order for the driving current IDR to decrease, the reference voltage VREF should increase. However, when the reference voltage VREF increases, a maximum luminance of the display device may decrease, and therefore, the maximum grayscale voltage of the data voltage VDATA should increase. Here, the maximum grayscale voltage of the data voltage VDATA represents a data voltage when the input grayscale has a maximum grayscale (e.g., 255). The data voltage VDATA may be generated by dividing the data driving voltage AVDD. In order for the maximum grayscale voltage of the data voltage VDATA to increase, the data driving voltage AVDD should increase. In this case, since the data driving voltage AVDD increases, the power consumption may increase.

On the other hand, when the difference value VAR between the anode initialization voltage VAINT and the second power supply voltage ELVSS is small, the power consumption may decrease, but the display quality (e.g., the FFR characteristics and the TLS characteristics) may deteriorate. For example, when the difference value VAR between the anode initialization voltage VAINT and the second power supply voltage ELVSS is small, the display quality (e.g., the FFR characteristics and the TLS characteristics) may deteriorate, but black corresponding to a grayscale of zero may be completely implemented. Therefore, when the input grayscale is 0, the driving current IDR may be relatively large. (Here, the relatively large driving current IDR means that black corresponding to a grayscale of zero is completely implemented even if the driving current IDR is relatively large.) The magnitude of the driving current IDR is determined based on the gate-source voltage of the first transistor T1, and the gate-source voltage of the first transistor T1 is C_CHOLD/(C_CST+C_CHOLD) × (VDATA–VREF) + VTH. Since black corresponding to a grayscale of zero may be completely implemented even if the driving current IDR is large, the reference voltage VREF may be small. When the reference voltage VREF is small, the maximum luminance of the display device may be secured even if the maximum grayscale voltage of the data voltage VDATA is small. The data voltage VDATA may be generated by dividing the data driving voltage AVDD. When the maximum grayscale voltage of the data voltage VDATA is small, the data driving voltage AVDD may decrease. In this case, since the data driving voltage AVDD decreases, the power consumption may decrease.

As such, the power consumption and the display quality (e.g., the FFR characteristics and the TLS characteristics) may vary according to the reference voltage VREF, the data driving voltage AVDD, and the difference value VAR between the anode initialization voltage VAINT and the second power supply voltage ELVSS. Therefore, the display device according to embodiments of the disclosure may control the reference voltage VREF, the data driving voltage AVDD, and the difference value VAR between the anode initialization voltage VAINT and the second power supply voltage ELVSS according to an average picture level APL of the input image data IMG.

Here, the display panel 100 of the display device may include multiple pixels PX, and each of the pixels PX may have a luminance. The average picture level of the input image data IMG corresponds to an average of the luminances of the pixels PX of the display device. The average picture level of the input image data IMG may be expressed in terms of luminance, grayscale, percentage, etc.

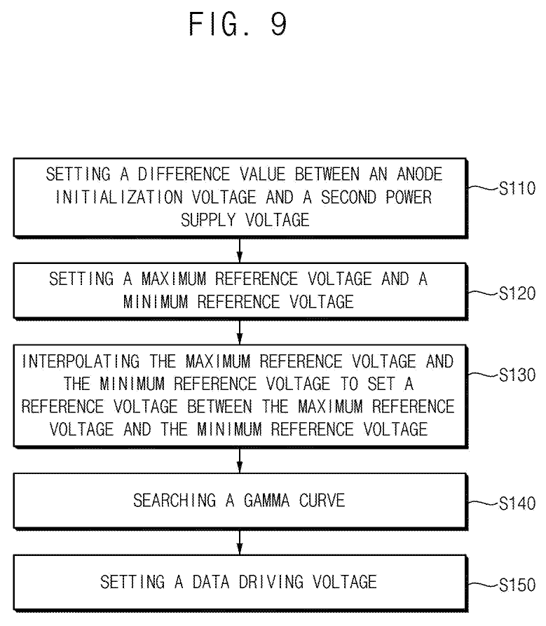

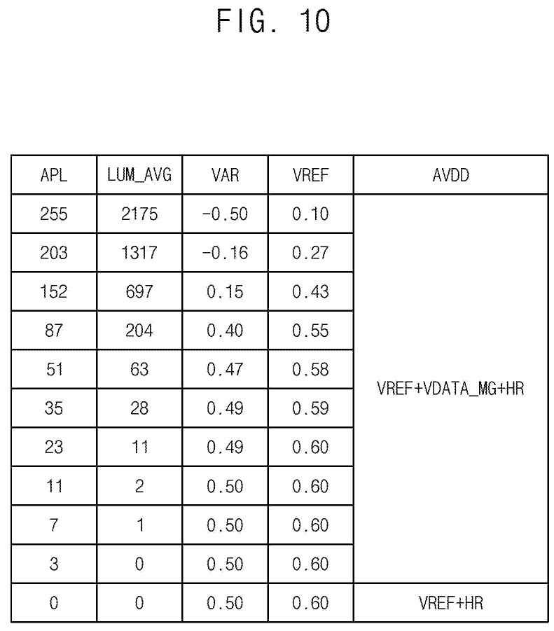

FIG. 9 is a flowchart showing a method of setting voltages VAR, VREF, and AVDD according to an average picture level APL of input image data IMG according to an embodiment of the disclosure. FIG. 10 is a table showing voltages VAR, VREF, and AVDD set according to a voltage setting method of FIG. 9.

Referring to FIGS. 1 to 10, to reduce the power consumption while maintaining the display quality (e.g., the FFR characteristics and the TLS characteristics), the reference voltage VREF, the data driving voltage AVDD, and the difference value VAR between the anode initialization voltage VAINT and the second power supply voltage ELVSS may be preset according to an average picture level APL of the input image data IMG.

For example, a range of the input grayscale may be 0 to 255 inclusive. Here, the grayscale of zero may represent black, and the grayscale of 255 may represent white.

When the range of the input grayscale is zero to 255 inclusive, the range of the average picture level APL of the input image data IMG may be zero to 255. Here, the input grayscale represents a value for a pixel PX, and the average picture level APL of the input image data IMG represents a value for all pixels PX.

According to the average picture level APL of the input image data IMG, an average luminance LUM_AVG (i.e., an average of the luminances of the pixels PX of the display device) of the display device may vary. For example, as the average picture level APL of the input image data IMG increases, the average luminance LUM_AVG of the display device may increase. For example, when the average picture level APL of the input image data IMG has a grayscale of 0, 3, 7, 11, 23, 35, 51, 87, 152, 203, and 255, respectively, the average luminance LUM_AVG of the display device may be 0 nits, 0 nit, 1 nits, 2 nits, 11 nits, 28 nits, 63 nits, 204 nits, 697 nits, 1317 nits, and 2175 nits, respectively. However, the average luminance LUM_AVG of the display device according to the average picture level APL of the input image data IMG may vary according to a specification of the display device. Therefore, the average luminance LUM_AVG of the display device according to the average picture level APL of the input image data IMG is not necessarily limited thereto.

A voltage setting method may include setting the difference value VAR between the anode initialization voltage VAINT and the second power supply voltage ELVSS (step S110), setting a maximum reference voltage (i.e., a maximum value of the reference voltage VREF) and a minimum reference voltage (i.e., a minimum value of the reference voltage VREF) (step S120), setting a reference voltage between the maximum reference voltage and the minimum reference voltage by interpolating the maximum reference voltage and the minimum reference voltage (step S130), searching a gamma curve (step S140), and setting the data driving voltage AVDD (step S150).

The difference value VAR between the anode initialization voltage VAINT and the second power supply voltage ELVSS may be set according to the average picture level APL of the input image data IMG (step S110). As described above, the display quality (e.g., the FFR characteristics and the TLS characteristics) may be controlled according to the difference value VAR between the anode initialization voltage VAINT and the second power supply voltage ELVSS. As the average picture level APL of the input image data IMG decreases, the driving current IDR should be finely adjusted, and therefore, the display quality (e.g., the FFR characteristics and the TLS characteristics) may deteriorate. Therefore, as the average picture level APL of the input image data IMG decreases, the difference value VAR between the anode initialization voltage VAINT and the second power supply voltage ELVSS may increase, and therefore the display quality (e.g., the FFR characteristics and the TLS characteristics) may improve. For example, when the average picture level APL of the input image data IMG has a grayscale of 0, 3, 7, 11, 23, 35, 51, 87, 152, 203, and 255, respectively, the difference value VAR between the anode initialization voltage VAINT and the second power supply voltage ELVSS is 0.50 Volts, 0.50 Volts, 0.50 Volts, 0.50 Volts, 0.49 Volts, 0.49 Volts, 0.47 Volts, 0.40 Volts, 0.15 Volts, -0.16 Volts, and -0.50 Volts, respectively. However, the difference value VAR between the anode initialization voltage VAINT and the second power supply voltage ELVSS according to the average picture level APL of the input image data IMG may vary according to the specification of the display device. Therefore, the difference value VAR between the anode initialization voltage VAINT and the second power supply voltage ELVSS according to the average picture level APL of the input image data IMG is not necessarily limited thereto.

The maximum reference voltage and the minimum reference voltage may be set according to the difference value VAR between the anode initialization voltage VAINT and the second power supply voltage ELVSS (step S120). For example, as described above, the maximum reference voltage and the minimum reference voltage may vary according to the difference value VAR between the anode initialization voltage VAINT and the second power supply voltage ELVSS. As the difference VAR between the anode initialization voltage VAINT and the second power supply voltage ELVSS increases, the reference voltage VREF may decrease. In other words, as the average picture level APL of the input image data IMG increases, the reference voltage VREF may increase. For example, when the average picture level APL of the input image data IMG has a zero grayscale, the maximum reference voltage (i.e., the maximum value of the reference voltage VREF) may be 0.60 Volts. For example, when the average picture level APL of the input image data IMG has a grayscale of 255, the minimum reference voltage (i.e., the minimum value of the reference voltage VREF) may be 0.10 Volts. However, the maximum reference voltage and the minimum reference voltage may vary according to the specification of the display device. Therefore, the maximum reference voltage and the minimum reference voltage according to the average picture level APL of the input image data IMG are not necessarily limited thereto.

The reference voltage between the maximum reference voltage and the minimum reference voltage may be set by interpolating the maximum reference voltage and the minimum reference voltage (step S130). For example, unlike the difference value VAR between the anode initialization voltage VAINT and the second power supply voltage ELVSS which directly affects the display quality (e.g., the FFR characteristics and the TLS characteristics), the reference voltage VREF may indirectly affect the display quality (e.g., the FFR characteristics and the TLS characteristics). Therefore, the reference voltage between the maximum reference voltage and the minimum reference voltage, excluding the maximum reference voltage and the minimum reference voltage, may be set by interpolation. For example, when the average picture level APL of the input image data IMG has a grayscale of 3, 7, 11, 23, 35, 51, 87, 152, and 203, respectively, the reference voltage between the maximum reference voltage and the minimum reference voltage may be 0.60 Volts, 0.60 Volts, 0.60 Volts, 0.60 Volts, 0.59 Volts, 0.58 Volts, 0.55 Volts, 0.43 Volts, and 0.27 Volts. However, the reference voltage between the maximum reference voltage and the minimum reference voltage according to the average picture level APL of the input image data IMG may vary depending on the specifications of the display device. Therefore, the reference voltage between the maximum reference voltage and the minimum reference voltage according to the average picture level APL of the input image data IMG is not necessarily limited thereto.

The gamma curve may be searched (step S140). For example, the gamma curve represents the luminance of each of the pixels PX according to the input grayscale. The user's eyes are good (i.e., is sensitive) at distinguishing a difference between dark areas but not good at distinguishing a difference between bright areas. The gamma curve may be set to a luminance of each of pixels PX according to an input grayscale which is optimized for the user's eyes, and the gamma curve optimized for the user's eyes may be referred to as a target gamma curve. A gamma curve represented by the reference voltage VREF and the difference value VAR between the anode initialization voltage VAINT and the second power supply voltage ELVSS may be searched, and may be compared with the target gamma curve.

The data driving voltage AVDD may be set according to the reference voltage VREF and the difference value VAR between the anode initialization voltage VAINT and the second power supply voltage ELVSS (step S150). For example, the data driving voltage AVDD may be set such that the target gamma curve may be implemented. The data driving voltage AVDD may vary according to the reference voltage VREF and the difference value VAR between the anode initialization voltage VAINT and the second power supply voltage ELVSS. As the reference voltage VREF increases and the difference value VAR between the anode initialization voltage VAINT and the second power supply voltage ELVSS increases, the data driving voltage AVDD may decrease. In other words, as the average picture level APL of the input image data IMG increases, the data driving voltage AVDD may increase. In an embodiment, when the average picture level APL of the input image data IMG is greater than an APL threshold, the data driving voltage AVDD may be a sum of the reference voltage VREF, a maximum grayscale voltage VDATA_MG of the data voltage VDATA, and a headroom HR. When the average picture level APL of the input image data IMG is less than or substantially equal to the APL threshold, the data driving voltage AVDD may be a sum of the reference voltage VREF and the headroom HR. Here, the maximum grayscale voltage VDATA_MG of the data voltage VDATA represents the data voltage when the input grayscale has the maximum grayscale (e.g., 255), and the headroom HR represents a margin. The data voltage VDATA may be generated by dividing the data driving voltage AVDD. For example, the APL threshold value may have a zero grayscale, the maximum grayscale voltage VDATA_MG of the data voltage VDATA may be 3 Volts, and the headroom HR may be 0.3 Volts. For example, when the average picture level APL of the input image data IMG has a grayscale of zero, the data driving voltage AVDD may be 0.90 (= 0.60 + 0.3) Volts. For example, when the average picture level APL of the input image data IMG has a grayscale of 3, 7, 11, 23, 35, 51, 87, 152, 203, and 255, respectively, the data driving voltage AVDD is 3.90 (= 0.60 + 3 + 0.3) Volts, 3.90 (= 0.60 + 3 + 0.3) Volts, 3.90 (= 0.60 + 3 + 0.3) Volts, 3.90 (= 0.60 + 3 + 0.3) Volts, 3.89 (= 0.59 + 3 + 0.3) Volts, 3.88 (= 0.58 + 3 + 0.3) Volts, 3.85 (= 0.55 + 3 + 0.3) Volts, 3.77 (= 0.43 + 3 + 0.3) Volts, 3.61 (= 0.27 + 3 + 0.3) Volts, and 3.44 (= 0.10 + 3 + 0.3) Volts. However, the data driving voltage AVDD may vary according to the specification of the display device. Therefore, the data driving voltage AVDD according to the average picture level APL of the input image data IMG is not necessarily limited thereto.

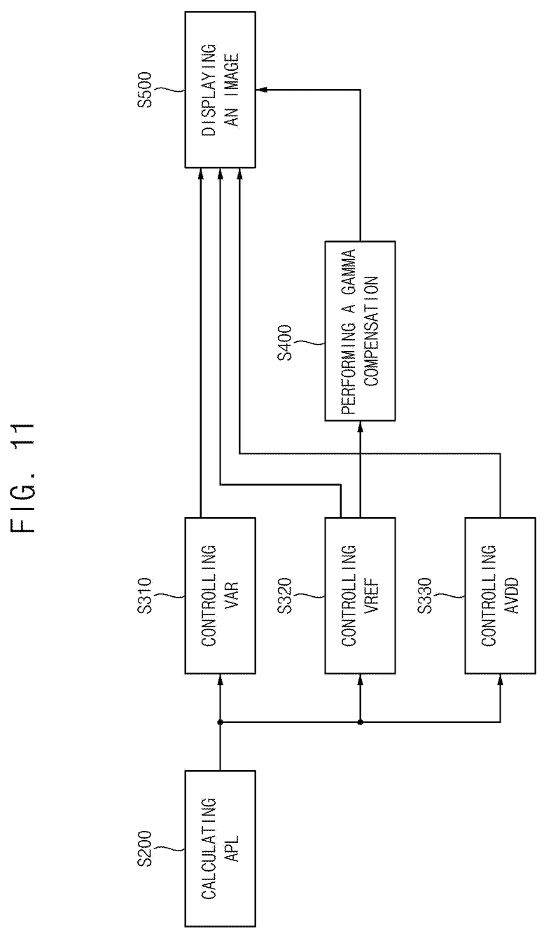

FIG. 11 is a flowchart showing a method of controlling voltages VAR, VREF, AVDD, VDATA according to an average picture level APL of an input image data IMG according to an embodiment of the disclosure.

Referring to FIGS. 1 to 11, to reduce the power consumption while maintaining the display quality (e.g., the FFR characteristics and the TLS characteristics) according to an embodiment of the disclosure, the input image data IMG, the reference voltage VREF, the data driving voltage AVDD, and the difference value VAR between the anode initialization voltage VAINT and the second power supply voltage ELVSS may be controlled according to the average picture level APL of the input image data IMG, and a gamma compensation may be performed. Here, the reference voltage VREF, the data driving voltage AVDD, and the difference value VAR between the anode initialization voltage VAINT and the second power supply voltage ELVSS may be values that are preset according to the average picture level APL of the input image data IMG.

A voltage control method may include calculating the average picture level APL of the input image data IMG (step S200), controlling the difference value VAR between the anode initialization voltage VAINT and the second power supply voltage ELVSS (step S310), controlling the reference voltage VREF (step S320), controlling the data driving voltage AVDD (step S330), performing a gamma compensation (step S400), and displaying an image (step S500).

A driving controller 200 may calculate the average picture level APL of the input image data IMG (step S200). For example, the driving controller 200 may calculate the average picture level APL of the input image data IMG by calculating the average of the luminances of the pixels PX of the display device based on the input image data IMG. The driving controller 200 may calculate the average picture level APL of the input image data IMG over multiple frames. In a sixty-fifth frame for example, the driving controller 200 may calculate the average picture level APL of the input image data IMG using first to sixty-fourth frames. In the sixty-sixth frame for example, the driving controller 200 may calculate the average picture level APL using the second to sixty-fifth frames. Accordingly, the reference voltage VREF, the data driving voltage AVDD, and the difference value VAR between the anode initialization voltage VAINT and the second power supply voltage ELVSS may change smoothly and not abruptly.

The driving controller 200 may control the difference value VAR between the anode initialization voltage VAINT and the second power supply voltage ELVSS according to the average picture level APL of the input image data IMG (step S310). The driving controller 200 may control the reference voltage VREF according to the average picture level APL of the input image data IMG (step S320). The driving controller 200 may control the data driving voltage AVDD according to the average picture level APL of the input image data IMG (step S330). For example, the driving controller 200 may preset the reference voltage VREF, the data driving voltage AVDD, and the difference value VAR between the anode initialization voltage VAINT and the second power supply voltage ELVSS according to the average picture level APL of the input image data IMG. The reference voltage VREF, the data driving voltage AVDD, and the difference value VAR between the anode initialization voltage VAINT and the second power supply voltage ELVSS may be controlled according to the average picture level APL. The reference voltage VREF, the data driving voltage AVDD, and the difference value VAR between the anode initialization voltage VAINT and the second power supply voltage ELVSS may be substantially equally applied to the pixels PX of the display device. For example, when the average picture level APL of the input image data IMG has a grayscale of 152, the difference value VAR between the anode initialization voltage VAINT and the second power supply voltage ELVSS having 0.15 Volts, and the reference voltage VREF having 0.43 Volts may be applied to the pixels PX of the display device.

The driving controller 200 may perform a gamma compensation in which the data voltage VDATA is compensated based on the reference voltage VREF controlled according to the average picture level APL of the input image data IMG (step S400). For example, when the input grayscale is 255, the data voltage may be 3.0 Volts, and the reference voltage VREF for implementing the target gamma curve may be 0.10 Volts. In this case, VDATA-VREF of the driving current IDR should be 2.90 (=3.0-0.10) Volts. Since the reference voltage VREF having 0.43 Volts is substantially equally applied to the pixels PX of the display device, VDATA-VREF of the driving current IDR for which the data voltage VDATA is not compensated is 2.57 (=3.0-0.43). Therefore, to implement the target gamma curve, the data voltage VDATA may be compensated by 0.33 Volts, and VDATA-VREF may be 2.90 (=2.57+0.33) Volts. In other words, the data voltage VDATA may have 3.33 Volts, which is compensated by 0.33 Volts from 3.0 Volts.

An image may be displayed based on the reference voltage VREF, the data driving voltage AVDD, the compensated data voltage, and the difference value VAR between the anode initialization voltage VAINT and the second power supply voltage ELVSS according to the average picture level APL of the input image data IMG (step S500).

As such, the reference voltage VREF, the data driving voltage AVDD, and the difference value VAR between the anode initialization voltage VAINT and the second power supply voltage ELVSS may be controlled according to the average picture level APL of the input image data IMG. Accordingly, the display quality (e.g., the FFR characteristics and the TLS characteristics) may be maintained while the power consumption is reduced.

According to embodiments of the disclosure, a display device and an electronic device that includes the same allows for less power consumption while maintaining display quality. These goals are achieved by controlling each of a reference voltage VREF, a data driving voltage AVDD, and a difference value VAR between an anode initialization voltage VAINT and a second power supply voltage ELVSS based on an average picture level (APL) of the image input data.

In order to achieve these goals, a driving controller 200 of a display panel driver receives input image data IMG and determines an average picture level APL from multiple successive frames of input image data IMG. The average picture level APL may then be used to determine the reference voltage VREF, the data driving voltage AVDD, and the difference value VAR between the anode initialization voltage and the second power supply voltage. Then, the driving controller is configured to perform gamma compensation in which the data voltage is compensated based on the reference voltage. Then, the display device is configured to display the image based on the reference voltage VREF, the data driving voltage AVDD, the compensated data voltage, and the difference value between the anode initialization voltage and the second power supply voltage. Accordingly, the display quality can be maintained while power consumption may be reduced.

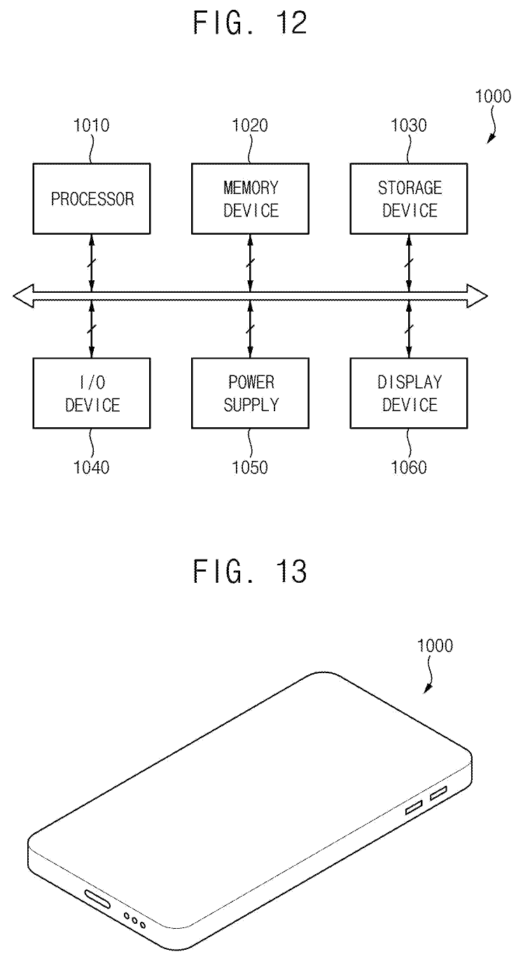

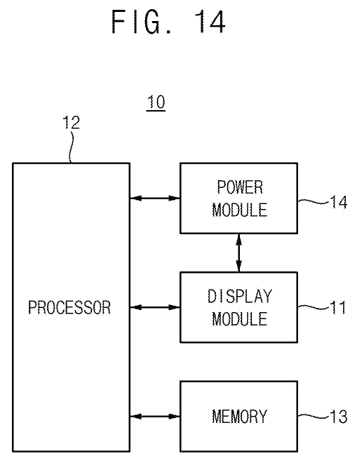

FIG. 12 is a block diagram showing an electronic device 1000 according to an embodiment of the disclosure. FIG. 13 is a diagram showing an example in which the electronic device 1000 of FIG. 12 is implemented as a smart phone.

Referring to FIGS. 1 to 13, the electronic device 1000 may include a processor 1010, a memory device 1020, a storage device 1030, an input/output (I/O) device 1040, a power supply 1050 and a display device 1060. Here, the display device 1060 may be the display device of FIG. 1. The electronic device 1000 may further include multiple ports for communicating with a video card, a sound card, a memory card, a universal serial bus (USB) device, other electronic devices, etc.

In an embodiment, as shown in FIG. 13, the electronic device 1000 may be implemented as a smart phone. However, the electronic device 1000 is not necessarily limited thereto. For example, the electronic device 1000 may be implemented as a cellular phone, a video phone, a smart pad, a smart watch, a tablet, a car navigation system, a computer monitor, a laptop, a head mounted display (HMD) device, and the like.

The processor 1010 may perform various computing functions or various tasks. The processor 1010 may be a micro-processor, a central processing unit (CPU), an application processor (AP), and the like. The processor 1010 may be coupled to other components via an address bus, a control bus, a data bus, etc. Further, the processor 1010 may be coupled to an extended bus such as a peripheral component interconnection (PCI) bus.

The processor 1010 may output the input image data IMG and the input control signal CONT to the driving controller 200 of FIG. 1.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, and the like and/or at least one volatile memory device such as a dynamic random access memory (DRAM) device, a static random access memory (SRAM) device, a mobile DRAM device, and the like.

The storage device 1030 may include a solid state drive (SSD) device, a hard disk drive (HDD) device, a CD-ROM device, and the like. The I/O device 1040 may include an input device such as a keyboard, a keypad, a mouse device, a touch-pad, a touch-screen, and the like and an output device such as a printer, a speaker, and the like. In some embodiments, the display device 1060 may be included in the I/O device 1040. The power supply 1050 may supply power for operations of the electronic device 1000. The display device 1060 may be coupled to other components via the buses or other communication links.

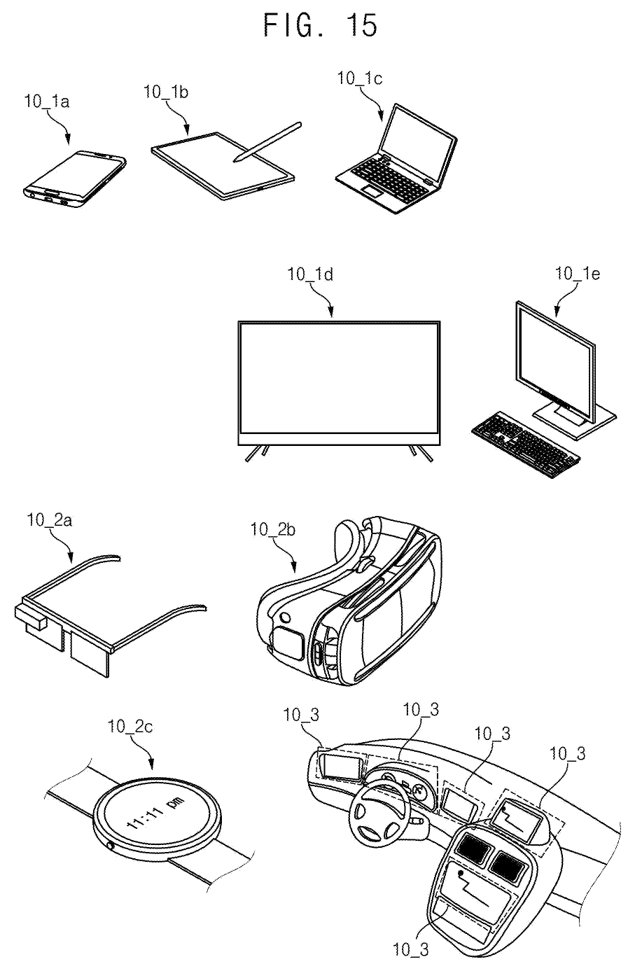

FIG. 14 is a block diagram showing an electronic device 10 according to an embodiment of the disclosure. FIG. 15 are schematic diagrams showing electronic devices of FIG. 14.

Referring to FIG. 14, the electronic device 10 according to an embodiment may include a display module 11, a processor 12, a memory 13 and a power module 14.

The display device according to the embodiment of the disclosure may be applied to various electronic devices.

In an embodiment, the electronic device 10 may include the display device of FIG. 1. An operation of the display device included in the electronic device 10 may be the same as the operation of the display device explained referring to FIGS. 1 to 11. The electronic device 10 may further include a module or a device having additional functions in addition to the display device.

The processor 12 may include at least one of a central processing unit (CPU), an application processor (AP), a graphic processing unit (GPU), a communication processor (CP), an image signal processor (ISP) and a controller.

In an embodiment, the processor 12 may supply the input control signal CONT of FIG. 1 and the input image data IMG of FIG. 1 to the driving controller 200 included in the display device of FIG. 1.

In an embodiment, the processor 12 may be divided into multiple processors in a functional or structural perspective. For example, the processor 12 may include a main processor as a first driving chip type, including the central processing unit and an auxiliary processor as a second driving chip type, and a controller that receives an image signal from the main processor and processing the image signal to match interface specifications of the display module 11. For example, the auxiliary processor may include the driving controller 200 included in the display device of FIG. 1. Thus, the main processor may supply the input control signal CONT FIG. 1 and the input image data IMG of FIG. 1 to the auxiliary processor. The auxiliary processor may process the image signal based on the input control signal CONT and the input image data IMG.

The memory 13 may include at least one of a nonvolatile memory and a volatile memory. Data information required for the operation of the processor 12 or the display module 11 may be stored in the memory 13. When the processor 12 executes an application stored in the memory 13, the input control signal CONT and/or the input image data IMG may be transmitted to the display module 11, and the display module 11 may process the input control signal CONT and/or the input image data IMG and may output image information through a display area.

The power module 14 may include a power supply module, such as a power adapter or a battery device, and a power conversion module that converts power supplied by the power supply module to generate power required for the operation of the electronic device 10.

At least one of the elements of the electronic device 10 may be included in the display device according to embodiments of the disclosure. A part of a single functional module may be included in the display device and another part of the single functional module may be external to the display device. For example, the display module 11 may be included in the display device but the processor 12, the memory 13 and the power module 14 may be included in another device in the electronic device 10 which is external to the display device.

Referring to FIG. 15, the various electronic devices including the display device according to the embodiments may be embodied as a smartphone 10_1a, a tablet 10_1b, a notebook / laptop computer 10_1c, a television 10_1d, a computer monitor 10_1e, wearable electronic devices including a display module such as smart glasses 10_2a, a head mounted display 10_2b and a smart watch 10_2c, and vehicle electronic devices 10_3 including display modules such as a CID (center information display), a room mirror display disposed on an instrument panel, center fascia, and a dashboard of a vehicle. The electronic device 10 might not necessarily be limited to the electronic devices for displaying image, the wearable electronic devices and the vehicle electronic devices 10_3.

According to the driver, the display device including the driver, and the electronic device including the driver of an embodiment of the disclosure as explained above, the power consumption of the display device may be reduced.

The foregoing is illustrative of the disclosure and is not to be construed as limiting thereof. Although a few example embodiments of the disclosure have been described, those skilled in the art will readily appreciate that many modifications are possible in the example embodiments without materially departing from the novel teachings and advantages of the disclosure. Accordingly, all such modifications are intended to be included within the scope of the disclosure as defined in the claims. In the claims, means-plus-function clauses are intended to cover the structures described herein as performing the recited function and not only structural equivalents but also equivalent structures. Therefore, it is to be understood that the foregoing is illustrative of the disclosure and is not to be construed as limited to the specific example embodiments disclosed, and that modifications to the disclosed example embodiments, as well as other example embodiments, are intended to be included within the scope of the appended claims. The disclosure is defined by the following claims, with equivalents of the claims to be included therein.

What is claimed is:

1. A display device comprising:
a display panel including a pixel driven based on a first power supply voltage and a second power supply voltage; and
a display panel driver configured to generate a data driving voltage, configured to generate a gamma reference voltage by dividing the data driving voltage, configured to generate a data voltage based on input image data by dividing the data driving voltage and the gamma reference voltage, and configured to supply the data voltage to the pixel, wherein:
the pixel includes:
a driving transistor configured to generate a driving current;,
a data write transistor configured to supply the data voltage to the driving transistor;
a reset transistor configured to supply a reference voltage to a gate electrode of the driving transistor;
a light emitting diode configured to emit light based on the driving current; and
an anode initialization transistor configured to supply an anode initialization voltage to an anode electrode of the light emitting diode, and
the display panel driver is further configured to control the reference voltage, the data driving voltage, and a difference value between the anode initialization voltage and the second power supply voltage based on an average picture level (APL) of the input image data.

2. The display device of claim 1, wherein the display panel driver is further configured to reduce the difference value between the anode initialization voltage and the second power supply voltage when the average picture level of the input image data increases.

3. The display device of claim 2, wherein the display panel driver is further configured to reduce the reference voltage when the average picture level of the input image data increases.

4. The display device of claim 3, the display panel driver is further configured to perform a gamma compensation to compensate for the data voltage based on the reference voltage.

5. The display device of claim 3, wherein the display panel driver is further configured to increase the data driving voltage when the average picture level of the input image data increases.

6. The display device of claim 5, wherein:
the data driving voltage is a sum of the reference voltage, a maximum grayscale voltage of the data voltage, and a headroom when the average picture level of the input image data is greater than an APL threshold, and
the data driving voltage is a sum of the reference voltage and the headroom when the average picture level of the input image data is less than or substantially equal to the APL threshold.

7. The display device of claim 1, wherein the display panel driver is further configured to calculate the average picture level of the input image data over a plurality of frames.

8. The display device of claim 1, wherein:
the driving transistor includes a gate electrode connected to a first node, a first electrode, and a second electrode connected to a second node,
the data write transistor includes a gate electrode configured to receive a data write gate signal, a first electrode configured to receive the data voltage, and a second electrode connected to the first node,
the reset transistor includes a gate electrode configured to receive a reset gate signal, a first electrode configured to receive the reference voltage, and a second electrode connected to the first node,
the anode initialization transistor includes a gate electrode configured to receive an initialization gate signal, a first electrode configured to receive the anode initialization voltage, and a second electrode connected to a third node, and
the light emitting diode includes the anode electrode connected to the third node and a cathode electrode configured to receive the second power supply voltage.

9. The display device of claim 8, wherein:
the pixel further includes a first light emitting control transistor and a second light emitting control transistor configured to control light emission of the light emitting diode,
the first light emitting control transistor includes a gate electrode configured to receive a first emission signal, a first electrode configured to receive the first power supply voltage, and a second electrode connected to the first electrode of the driving transistor, and
the second light emitting control transistor includes a gate electrode configured to receive a second emission signal, a first electrode connected to the second node, and a second electrode connected to the third node.

10. The display device of claim 9, wherein the pixel further includes a storage capacitor including a first electrode connected to the first node and a second electrode connected to the second node.

11. The display device of claim 10, wherein:
the driving transistor further includes a back gate electrode connected to the second node, and
the pixel further includes a hold capacitor including a first electrode configured to receive the first power supply voltage and a second electrode connected to the second node.

12. An electronic device comprising:
a display panel including a pixel driven based on a first power supply voltage and a second power supply voltage;
a display panel driver configured to generate a data driving voltage, configured to generate a gamma reference voltage by dividing the data driving voltage, configured to generate a data voltage based on input image data by dividing the data driving voltage and the gamma reference voltage , and configured to supply the data voltage to the pixel; and
a processor configured to control the display panel driver, wherein:
the pixel includes:
a driving transistor configured to generate a driving current;
a data write transistor configured to supply the data voltage to the driving transistor;
a reset transistor configured to supply a reference voltage to a gate electrode of the driving transistor;
a light emitting diode configured to emit light based on the driving current; and
an anode initialization transistor configured to supply an anode initialization voltage to an anode electrode of the light emitting diode, and
the display panel driver is further configured to control the reference voltage, the data driving voltage, and a difference value between the anode initialization voltage and the second power supply voltage based on an average picture level (APL) of the input image data.

13. The electronic device of claim 12, wherein the display panel driver is further configured to reduce the difference value between the anode initialization voltage and the second power supply voltage when the average picture level of the input image data increases.

14. The electronic device of claim 13, wherein the display panel driver is further configured to reduce the reference voltage when the average picture level of the input image data increases.

15. The electronic device of claim 14, the display panel driver is further configured to perform a gamma compensation to compensate for the data voltage based on the reference voltage.

16. The electronic device of claim 14, wherein the display panel driver is further configured to increase the data driving voltage when the average picture level of the input image data increases.

17. The electronic device of claim 16, wherein:
the data driving voltage is a sum of the reference voltage, a maximum grayscale voltage of the data voltage, and a headroom when the average picture level of the input image data is greater than an APL threshold, and
the data driving voltage is a sum of the reference voltage and the headroom when the average picture level of the input image data is less than or substantially equal to the APL threshold.

18. The electronic device of claim 12, wherein the display panel driver is further configured to calculate the average picture level of the input image data over a plurality of frames.

19. The electronic device of claim 12, wherein:
the driving transistor includes a gate electrode connected to a first node, a first electrode, and a second electrode connected to a second node,
the data write transistor includes a gate electrode configured to receive a data write gate signal, a first electrode configured to receive the data voltage, and a second electrode connected to the first node,
the reset transistor includes a gate electrode configured to receive a reset gate signal, a first electrode configured to receive the reference voltage, and a second electrode connected to the first node,
the anode initialization transistor includes a gate electrode configured to receive an initialization gate signal, a first electrode configured to receive the anode initialization voltage, and a second electrode connected to a third node, and
the light emitting diode includes the anode electrode connected to the third node and a cathode electrode configured to receive the second power supply voltage.

20. The electronic device of claim 19, wherein:
the pixel further includes a first light emitting control transistor and a second light emitting control transistor configured to control light emission of the light emitting diode,
the first light emitting control transistor includes a gate electrode configured to receive a first emission signal, a first electrode configured to receive the first power supply voltage, and a second electrode connected to the first electrode of the driving transistor, and
the second light emitting control transistor includes a gate electrode configured to receive a second emission signal, a first electrode connected to the second node, and a second electrode connected to the third node.
